(19) United States
(12) Patent Application Publication
(10) Pub. No.: US 2008/0202924 A1
(43) Pub. Date: Aug. 28, 2008

(54) Power Source Arrangement For Multiple-Target Sputtering System

(76) Inventors: Terry Bluck, Santa Clara, CA (US); Patrick R. Ward, San Jose, CA (US); Michael S. Barnes, San Ramon, CA (US)

Correspondence Address: NIXON PEABODY, LLP, 401 9TH STREET, NW, SUITE 900, WASHINGTON, DC, 20004-2128, US

(21) Appl. No.: 12/032,525

(22) Filed: Feb. 15, 2008

Related U.S. Application Data
(60) Provisional application No. 60/890,243, filed on Feb. 16, 2007.

(51) Int. Cl. C23C 14/34

(52) U.S. Cl. 204/298.08

(57) ABSTRACT

An arrangement for concurrently powering a plurality of sputtering sources. A power supply is coupled to a charge accumulator. The charge accumulator is coupled to several sputtering sources via switching devices. The duty cycle of each switching device is used to individually control the power delivered to each sputtering source. In another arrangement, a power source is coupled to an impedance match circuit. The impedance match circuit is coupled to several sputtering sources via several balance elements. Each balance element is operated to individually control the power delivered to the sputtering source.

### CROSS-REFERENCE TO RELATED APPLICATIONS

This Application claims priority from U.S. Provisional Application Ser. No. 60/890,243, filed Feb. 16, 2007, which is incorporated herein by reference in its entirety.

### BACKGROUND

1. Field of the Invention

The general field of the invention relates to sputtering technology and, more specifically, to a unique power source arrangement for multiple-magnetron sputtering system.

2. Related Arts

Sputtering technology is well known in the art and is used for, among others, thin layer formation. This technology is used in, for example, semiconductor fabrication and hard disk fabrication. An example of a system utilizing sputtering chambers for hard disk fabrication is disclosed in U.S. Pat. No. 6,919,001, to Fairbaim et al. In such systems, the material to be deposited on a substrate is provided in the form of a target, and a magnetron is used to sputter the target material onto the substrate. In some systems the substrate is moved, while in others it is stationary.

FIG. 1 illustrates a conventional sputtering chamber using a magnetron. In FIG. 1, a vacuum chamber 100 has a substrate holder 105 which holds the substrate 110. In this particular example the substrate holder 105 is stationary, but in other configurations it may be movable for scanning the substrate 110 in front of the target assembly 125. Magnetron 115 includes magnets 120, situated behind the target 125. The target 125 has a layer of sputtering material 130 facing the substrate 110. The use of magnets 120 in magnetron 115 helps trapping secondary electrons in the plasma close to the target. The electrons follow helical paths around the magnetic field lines 135, thereby undergoing more ionizing collisions with plasma species near the target. This enhances the ionization of the plasma near the target, leading to a higher sputtering rate.

The target may be constructed from a target material 130 bonded to a backing plate. One function of the backing plate is to facilitate clamping of the target to the magnetron.

However, when the target material 130 has magnetic permeability, it is difficult to control the magnetic lines. Magnetic lines that emanate and terminate at the front faces of the magnets 120 may follow the path within the sputtering material 130, shown by the broken-line curves 137 in FIG. 1. The lines do not contribute to plasma species ionization, as they do not exit the target. On the other hand, magnetic lines that emanate from the side faces extend beyond the sides of the target, as shown by solid curves 135. Consequently, plasma confinement becomes difficult, especially when the target is small. That is, it is difficult to confine the plasma to a small area in front of the target.

With the advancement of technology, multiple layers of increasingly thin dimensions are sometimes needed to be deposited, especially in electronic technology, such as semiconductor devices and magnetic disks. Consequently, the substrates need to be sequentially exposed to several targets of different materials to form a “stack” of layers of different materials. For example, in modem recordable media, such as hard disks, interlaced layers of platinum and cobalt are deposited to form the magnetic recordable media. Each of these layers may be increasingly thin, for example, in the order of 5-20 angstrom. This is especially the case for newer perpendicular recording technology for hard disks. As a result, the substrate may need to be repeatedly cycled through different sputtering chambers, so as to deposit the stack of materials, sometimes consisting of up to 50 different layers.

Therefore, a system is needed that will enable better control over the plasma confinement so as to enhance the deposition rate. Furthermore, a system is needed that will enable faster deposition of multiple layers to reduce the cycling of substrates in many sputtering chambers. Additionally, when multiple-targets are used, a system is needed to enable powering the each of the targets in a cost effective and space conserving manner.

### SUMMARY

The following summary of the invention is provided in order to provide a basic understanding of some aspects and features of the invention. This summary is not an extensive overview of the invention, and as such it is not intended to particularly identify key or critical elements of the invention, or to delineate the scope of the invention. Its sole purpose is to present some concepts of the invention in a simplified form as a prelude to the more detailed description that is presented below.

Embodiments of the present invention provide a system that enhances control over the plasma confinement. Embodiments of the present invention also provide a system that reduces cycling of substrates in sputtering chambers. Embodiments of the invention enable power and control of multiple targets in a sputtering system in a cost effective and space conserving manner.

In one aspect of the invention, plasma confinement is improved by using a conductive shield. In a further aspect of the invention, plasma confinement is further improved by incorporating magnets in the conductive shield.

In one aspect of the invention, cycling of substrates in sputtering chambers is reduced by having multiple-materials targets in each chamber. In one aspect of the invention, a single power source is multiplexed to power several sputtering targets simultaneously. According to an aspect of the invention, a power supply arrangement for concurrently powering multiple sputtering sources is provided, comprising, a DC power supply; a charge accumulator coupled to the power supply; a plurality of power delivery switches, each coupled between the charge accumulator and a respective one of the multiple sputtering sources; and a controller activating each of the power delivery switches to individually control the amount of power delivered from the charge accumulator to each of the multiple sputtering sources. The charge accumulator may comprise a capacitor. The charge accumulator may comprise a plurality of capacitors, each coupled to one of the power delivery switches. The power supply arrangement may further comprise a plurality of charging switches, each coupled between the power supply and one of the plurality of capacitors. The controller may comprise a plurality of feedback circuits, each coupled to one of the power delivery switches. Each of the plurality of feedback circuits may further comprise arc detection circuit. The power supply arrangement may further comprise a plurality of discharge paths, each coupled one of the sputtering sources. Each of the a plurality of discharge paths may comprise a positive potential node. The controller may comprise a plurality of control circuits, each coupled to one of the power delivery switches.

According to an aspect of the invention, a power supply arrangement for concurrently powering multiple sputtering sources is provided, comprising, an RF power supply; an impedance match circuit coupled to the power supply, the impedance match circuit comprising at least one inductor and one capacitor; a plurality of variable capacitors, each coupled between the impedance match circuit and a respective one of the multiple sputtering sources; and a controller activating each of the variable capacitors to individually control the amount of power delivered from the impedance match circuit to each of the multiple sputtering sources. Each of the variable capacitors comprises a motorized variable vacuum capacitor. The controller may comprise a plurality of feedback loops, each coupled to a respective motorized variable vacuum capacitor. The power supply arrangement may further comprise a second RF power supply providing an output at 180 degrees phase to the output of the RF power supply; a second impedance match circuit coupled to the second RF power supply, the second impedance match circuit comprising at least one inductor and one capacitor; a second set of variable capacitors, each coupled between the second impedance match circuit and a respective one of the multiple sputtering sources that is not coupled to the impedance match circuit; and a second controller activating each of the variable capacitors of the second set to individually control the amount of power delivered from the second impedance match circuit. The plurality of sputtering sources may be arranged in successive order and may be coupled to the impedance match circuit and the second impedance match circuit in an interleaving order. Each of the variable capacitors may comprise a motorized variable vacuum capacitor. The second controller may comprise a second set of feedback loops, each coupled to a respective motorized variable vacuum capacitor.

According to an aspect of the invention, an arrangement for a sputtering system is provided, comprising: a first set of sputtering sources arranged serially; a second set of sputtering sources arranged serially and interleaving with the first set; a third set of sputtering sources arranged in opposing relationship to the first set; a fourth set of sputtering sources arranged serially and interleaving with the third set and in opposing relationship to the second set; first, second, third and fourth power sources, the first and third power sources providing in-phase output and the second and fourth power sources providing in-phase output, the second power source providing output in 180 degrees phase shift to the first power source; first, second, third and fourth match circuits coupled to the first, second, third and fourth power sources, respectively; first, second, third and fourth sets of balancing elements, the first set of balancing elements coupling the first impedance match circuit to the first set of sputtering sources, the second set of balancing elements coupling the second impedance match circuit to the second set of sputtering sources, the third set of balancing elements coupling the third impedance match circuit to the third set of sputtering sources, and the fourth set of balancing elements coupling the fourth impedance match circuit to the fourth set of sputtering sources. Each of the balancing elements may comprise a variable capacitor. Each variable capacitor may comprise a motorized vacuum variable capacitor. The arrangement may further comprise a plurality of feedback loops, each coupled to one of the motorized vacuum variable capacitor.

### BRIEF DESCRIPTION OF THE DRAWINGS

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements, and are not drawn to scale.

FIG. 1 illustrates a sputtering chamber according to the prior art.

FIG. 2 is a conceptual diagram showing a magnetron having enhanced plasma confinement according to an embodiment of the invention.

FIG. 3 is a conceptual diagram showing a magnetron having enhanced plasma confinement according to an embodiment of the invention.

FIG. 4 is a conceptual diagram showing a magnetron having enhanced plasma confinement according to an embodiment of the invention.

FIG. 5 illustrates a magnetron having enhanced plasma confinement according to an embodiment of the invention.

FIG. 6 illustrates the arrangement of magnets 650 around or inside the shield 645.

FIG. 7 illustrates part of a pass-by system according to an embodiment of the invention.

FIG. 8 illustrates a cross-section of chamber 710.

FIG. 9 illustrates a cross section of a sputtering source according to an embodiment of the invention.

FIG. 10 is a perspective view of a multiple-target sputtering source 1000 according to an embodiment of the invention.

FIG. 11 illustrates a shield that may be used for the embodiment of FIG. 10.

FIG. 12 illustrates a cross section of a process module according to an embodiment of the invention.

FIG. 13 illustrates a chamber having three sources, each having three magnetrons, according to embodiment of the invention.

FIGS. 14A-14C illustrate arrangements of power supplier for a plurality of sputtering targets according to embodiments of the invention.

FIG. 15 illustrates power modulation of the power supplier according to the embodiment of FIG. 14A.

FIG. 16 illustrates an arrangement of power supplier for a plurality of magnetrons according to another embodiment of the invention.

FIG. 17 illustrates an example of a sputtering chamber having multiple sputtering sources energized according to an embodiment of the invention.

### DETAILED DESCRIPTION

Various embodiments of the invention are generally directed to a system for sputtering layers of different materials on a substrate, such as a magnetic recordable media. The system may employ several sputtering chambers, each having a sputtering magnetron arrangement for several targets, or targets having several different materials. A metallic shield is provided between the target and the substrate. Magnets may be incorporated into the shield to assist in controlling the plasma confinement.

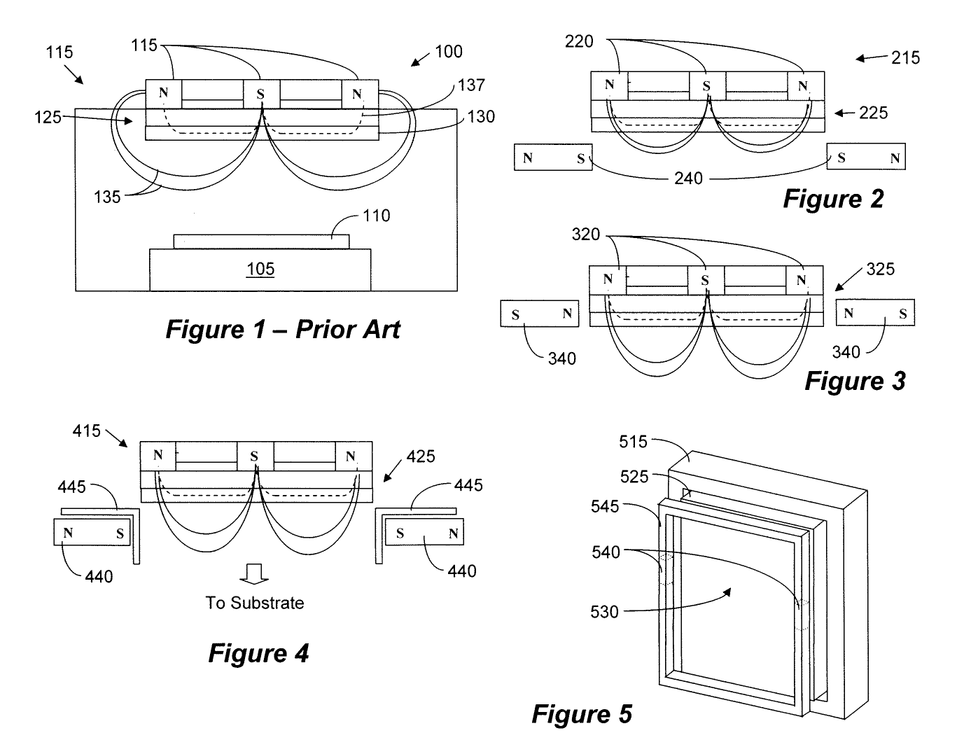

FIG. 2 is a conceptual diagram showing a magnetron having enhanced plasma confinement according to an embodiment of the invention. In the embodiment of FIG. 2, the same magnetron 215 as shown in FIG. 1 is used. However, magnets 240 have been added at a location extending beyond the front face of the target 225. In this configuration the poles of the magnets 240 are arranged so as to “pull” the magnetic lines at the outer periphery of the target, so as to cause the lines to assume a path inside, or close to the target. At the same time, the magnets 240 push on the lines that are at the center of the target, so as to keep all of the lines traversing the space at the front of the target to remain very close to the target.

In the particular example of FIG. 2, magnets 220 are arranged so that the north poles are at the sides of the target, while the south poles are at the center of the target. In such a configuration, magnets 240 should be placed so that their south poles are close to the target and the north poles point away from the target. In this way, the south poles of magnets 240 attract the magnetic lines emanating from the north poles of magnets 220, while repelling the magnetic lines towards the south poles of magnets 220, i.e., towards the center of the target 225. In this manner, the plasma is confined to the area just in front of the target, and does not extend beyond the sides of the target, as is the case with the arrangement of FIG. 1.

FIG. 3 is a conceptual diagram showing a magnetron having enhanced plasma confinement according to an embodiment of the invention. In the embodiment of FIG. 3, the same magnetron 315 as shown in FIG. 1 is used. However, magnets 340 have been added at or behind the front sputtering face of the target 325. In this configuration the poles of the magnets 340 are arranged so as to “push” the magnetic lines at the outer periphery of the target, so as to cause the lines to assume a path inside, or close to the target. By pushing the magnetic lines into the target, the target is saturated and the magnetic lines “pop out” from the face of the target, as shown in FIG. 3.

In the particular example of FIG. 3, magnets 320 are arranged so that the north poles are at the sides of the target, while the south poles are at the center of the target. In such a configuration, magnets 340 should be placed so that their north poles are close to the target and the south poles point away from the target. In this way, the north poles of magnets 320 repel the magnetic lines towards the sides of the target 325. In this manner, the plasma is confined to the area just in front of the target, and does not extend beyond the sides of the target, as is the case with the arrangement of FIG. 1.

FIG. 4 is a conceptual diagram showing a magnetron having enhanced plasma confinement according to an embodiment of the invention. In the embodiment of FIG. 4, the same magnetron 415 as shown in FIG. 1 is used. However, a plasma/sputtering shield 445 is placed in front of the sputtering face of target 425. In this embodiment the plasma/sputtering shield is made of conductive material, however, non-conductive material may also be used. Additionally, in this embodiment, magnets 440 have been added at or behind the face of the shield 445 which face target 425. By placing the plasma shield 445 and the magnets 440 in front of the target, enhanced plasma confinement is achieved. Additionally, enhanced control over species-sputtering is achieved, as the shield prevents sputtered species from reaching beyond the sides of the target.

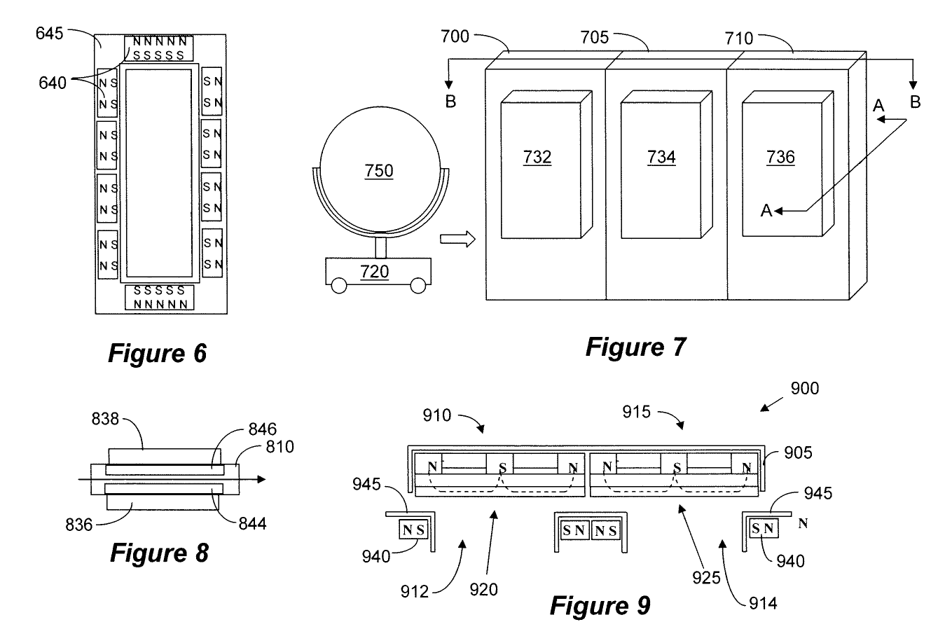

FIG. 5 illustrates a magnetron having enhanced plasma confinement according to an embodiment of the invention, implementing the concept illustrated in FIG. 4. In the embodiment of FIG. 5, magnetron 515 has a target 525 mounted thereto. A plasma/sputtering shield 545 is placed in front of the target 525, facing the sputtering face 530 of target 525. In this embodiment, magnets 540 are placed inside the shield 545, as illustrated by the broken line. FIG. 6 illustrates the arrangement of magnets 640 around or inside the shield 645. Such an arrangement may be used in the embodiment of FIG. 5.

FIG. 7 illustrates part of a pass-by system according to an embodiment of the invention, which is beneficial for sputtering consecutive layers of different materials on a substrate. The system in this example is particularly suitable for fabricating recording media, such as recording magnetic disks, which require many alternating layers of different materials sputtered on both sides of the substrate. In this particular example, only 3 chambers are shown, but this arrangement may be repeated to form any number of chambers, as illustrated by the above-cited '001 patent.

In the embodiment of FIG. 7, each of chambers 700, 705 and 710 may be constructed generally similarly to the chambers shown in the '001 patent. That is, each chamber has means for evacuating its processing section, means for transporting substrate carrier 720, and two sputtering sources on each side. In FIG. 7 only one sputter source, 732, 734 and 736, is shown for each chamber, as the other sputter source is on the other side, which is not visible in this perspective. Each sputter source has sputtering target of a given material, such that by selecting the proper targets and having the substrate carrier moving serially from chamber to chamber, layers of different materials may be sputtered on the substrate 750. For example, target 732 may have platinum, target 734 cobalt, and target 736 platinum, to thereby sputter alternating layers of platinum, cobalt, platinum, . . . , on the substrate.

FIG. 8 illustrates a cross-section along lines A-A of chamber 710. As shown in FIG. 8, the chamber 810 has two sputtering sources 836 and 838. Each of the sputtering sources is constructed similar to the embodiment shown in FIG. 5, so that each sputter source has a shield, 844, 846, and magnets (not shown) situated in the shields. The substrate moves along the path shown by the arrow. When the substrate is inside the chamber, the substrate holder may either stop until sputtering is completed, or continue move so as to scan the substrate in front of the sputtering sources. The substrate is placed very close to the shields, so that the sputtering species are contained to only within the window of the shield.

While the embodiment depicted in FIG. 7 is effective in sputtering alternating layers on a substrate, as noted above perpendicular recording technology requires many more layers than conventional parallel recording technology. On the other hand, the layers of perpendicular recording technology are very thin, thereby requiring short sputtering time. FIG. 9 illustrates a cross section of a sputtering source according to an embodiment of the invention, having multiple targets for discrete sputtering of separate layers.

In FIG. 9, a sputtering source has a housing 905, within which two magnetrons 910, 915 are situated. Each of magnetrons 910, 915, has a target 920, 925, respectively, mounted thereupon. The targets may be of same or different sputter material. A plasma/sputtering shield 945 is provided, which has two windows 912, 914, aligned with one of the targets 920, 925, respectively. In this embodiment, magnets 940 are also provide at or within the shield 945; however, in other embodiments the magnets may be omitted.

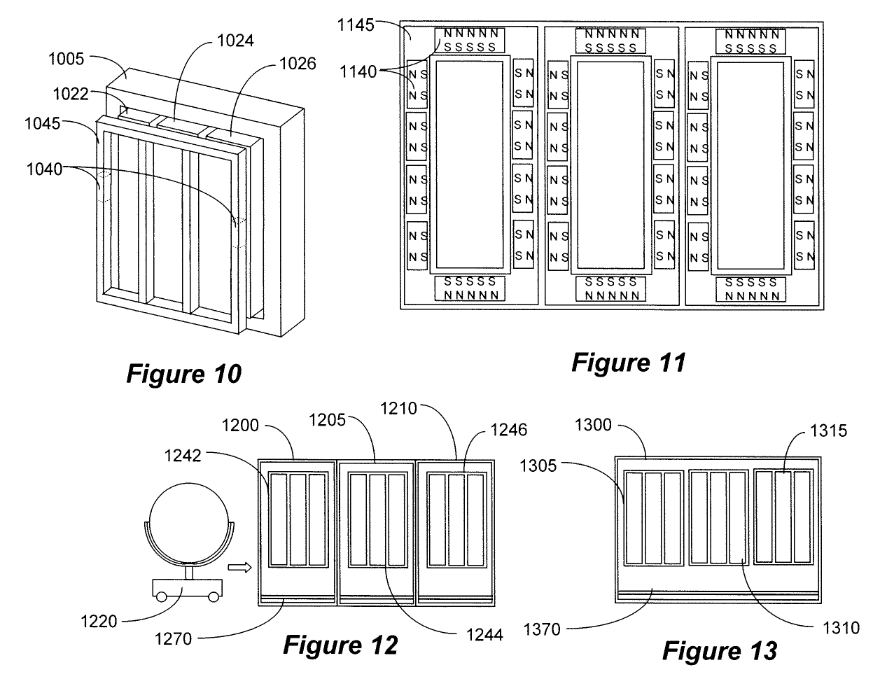

FIG. 10 is a perspective view of a multiple-target sputtering source 1000 according to an embodiment of the invention. The sputtering source of FIG. 10 is somewhat similar to that illustrated in FIG. 9, except that three magnetrons and three sputtering targets are provided within the single source 1000. As shown, the source's housing 1005 houses three targets, 1022, 1024, and 1026. The magnetrons driving these targets are not visible in this perspective. A shield 1045 is provided in front of the sputtering face of the targets. The shield 1045 has three windows, each aligned with one of the sputtering targets.

When a multiple-target sputtering source, such as source 1000, is installed in a sputtering chamber, such as any of chambers 700, 705, 710, of FIG. 7, three layers may be sputtered onto the substrate in one pass. Depending on the sputtering requirement, the targets may be of the same or of different sputtering material. For example, when using the system with a substrate carrier that is moving during sputtering, it is beneficial that the speed of the carrier be constant. Consequently, it is required that each process step be performed at the same amount of time as any other steps. The process time may therefore be controlled by determining the target's sputtering material. For example, if one wishes to sputter 5 angstrom of platinum and then 10 angstrom of cobalt, then one may use source 1000 with target 1022 being of platinum while targets 1024 and 1026 being of cobalt. In this way, when the carrier moves at constant speed, the layer of cobalt sputtered on the substrate may be twice as thick as that of platinum. On the other hand, if one wishes to have alternating layers of platinum and cobalt of the same thickness, then targets 1022 and 1026 would be of platinum, while target 1024 of cobalt.

While in FIG. 10 no magnets are shown with or inside the shield 1045, as with prior embodiments, the magnets may be incorporated inside the shield 1045. FIG. 11 illustrates a shield that may be used for the embodiment of FIG. 10. The shield 1145 has multiple windows, each aligned in front of one sputtering target, and incorporates magnets situated around each window. The shield may be constructed of a metallic material and the magnets may be enclosed inside the shield's frame. The windows of the shields enable accurate control of the plasma and of sputtered material. When the substrate is passed next to the shield, each target's sputtered material is confined to within the opening of the window, so that there is no cross-sputtering of the different material. Additionally, when magnets are placed within the shield, the plasma of each magnetron is confined within the window and no cross-talk of plasmas from different magnetrons occurs.

FIG. 12 illustrates a cross section of a process module according to an embodiment of the invention. The illustration of FIG. 12 is similar to a cross-section along lines B-B of FIG. 7, except that the chambers 1200, 1205 and 1210, employ the multiple-magnetron sputtering source of FIG. 10. In FIG. 12, three shields, 1242, 1244 and 1246 are used, each in front of a respective multiple magnetron sputtering source. Since the sputtering source has three magnetrons with three targets, each shield has three windows aligned with the targets. As can be appreciated, as many chambers as needed may be arranged in a single or multiple lines, just as shown in the '001 patent. The carrier 1220 may be transported on tracks 1270 at constant speed during sputtering, so that multiple layers are sputtered on the substrate. Moreover, each chamber may have more than one multiple-magnetron sputtering source. For example, FIG. 13 illustrates a chamber 1300 having three sources, 1305, 1310, and 1315, each having three magnetrons. Tracks 1370 are provided for carrier transport, so that the substrate is scanned across all nine targets and get coated with 9 layers of same or different materials.

Current fabrication technology contemplate depositing about 50 layers on each side of the disk, thereby requiring 50 sputtering sources, e.g., diode sputtering or magnetrons, on each side of the system. Using conventional technology, wherein each sputtering source is powered individually by a dedicated power source would require 50 power sources for the system. This would dramatically increase the cost and size of the system. On the other hand, connecting several sputtering sources to a single power source is problematic in that the power delivered to each sputtering source must be controlled accurately. This is why in the art each sputtering source is connected individually to a single power source.

Aspects of the invention provide power source arrangements that enable using a single power source to energize several sputtering sources while individually controlling the power delivered to each sputtering source. The following are embodiments of the invention enabling powering of multiple diode or magnetron sputtering sources using a single power source.

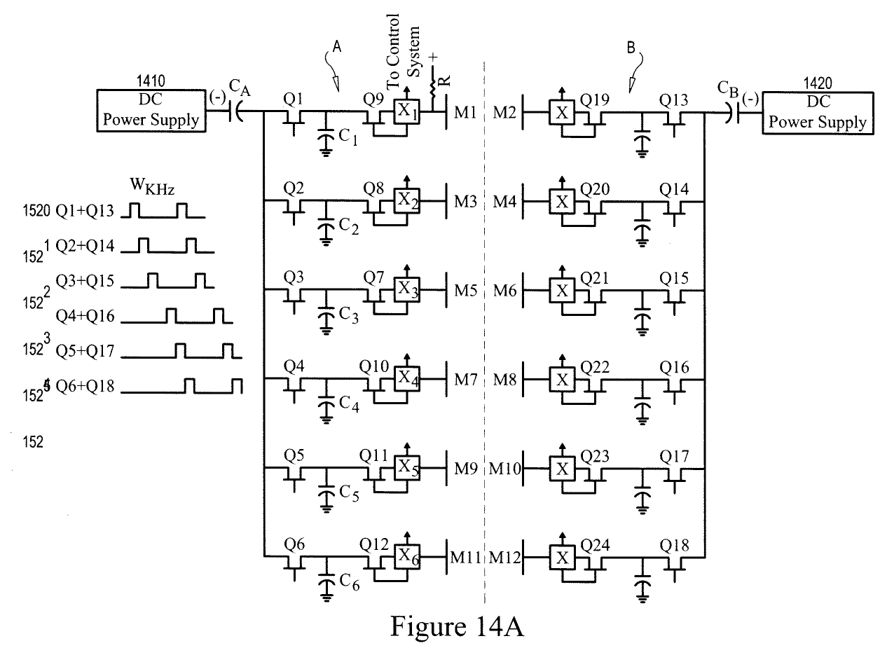

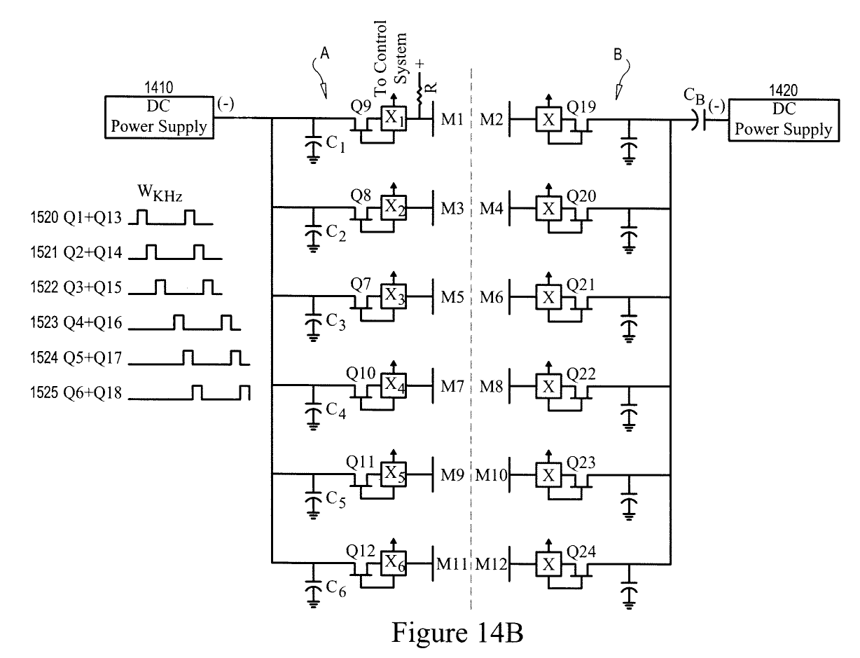

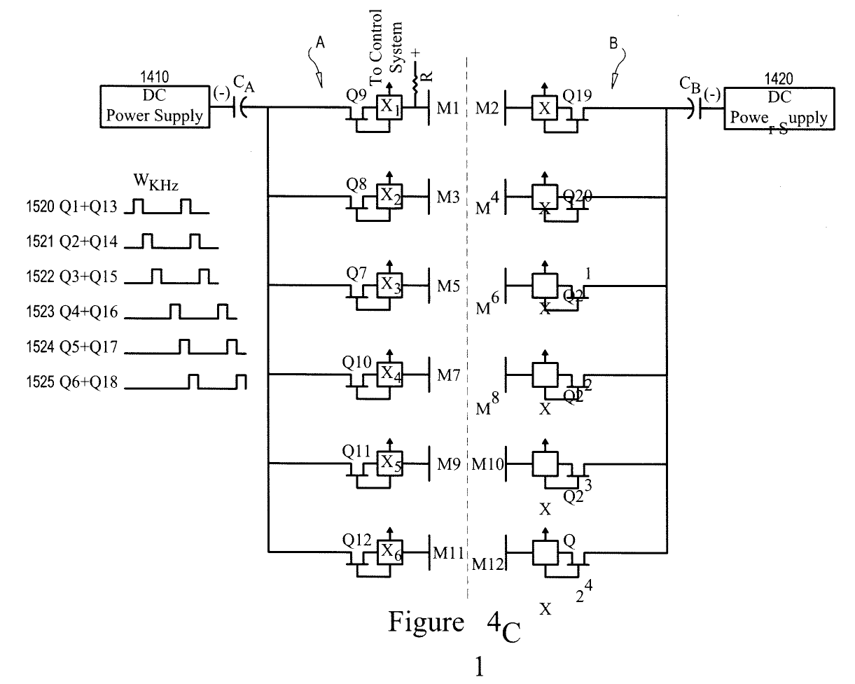

FIG. 14A illustrates an arrangement of power suppliers for a plurality of sputtering targets, according to an embodiment of the invention. This embodiment is optimized for diode sputtering targets, where the target is biased using a DC source. In FIG. 14A, a DC power source 1410 is utilized to energize one bank of sputtering targets on one side of the system (here, bank A comprises targets M1, M3, M5, M7, M9, M11), while another DC power source 1420 is utilized to energize the second bank of sputtering targets on the other side of the system (here, bank B comprises targets M2, M4, M6, M8, M10, M12). As shown, each opposing sputtering targets are paired so as to sputter material on both sides of the substrate (e.g., M1 paired with M2, M3 paired with M5, etc.). The substrate moves in between the two banks of sputtering targets, as illustrated by the broken-line arrow.

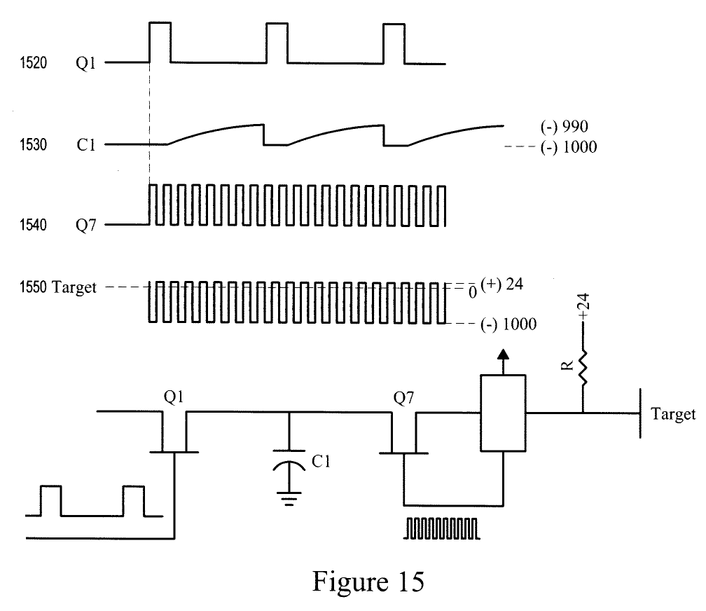

A coupling circuitry is provided to couple each sputtering target to the power sources and control the power delivered from the power source to the target. As the coupling circuitry is identical for each target, it will be explained with respect to target M1 (see, FIG. 15). The coupling circuitry of target M1 comprises charging switch Q1, capacitor C1, power delivery switch Q7, and control circuit X1.

Charging switch Q1 is used to connect to the negative terminal of the power supplier, so as to charge the capacitor C1. Here, the positive terminal of the power supplier is coupled to ground potential. The switch Q1 may be a MOSFET transistor, and its duty cycle (waveform 1520 in FIG. 15) is controlled so as to provide the proper charging to the capacitor (waveform 1530 in FIG. 15). As shown in FIG. 14 (waveforms 1520-1525), in this particular example the charging switches are operated so that the power supplier at each bank is coupled to only one capacitor at a time. This is not a requirement, as the power supplier may be coupled to more than one capacitor at a time, or even to all of the capacitors at the same time.

Power delivery switch Q7 coupled the capacitor C1 to the target M1, thereby causing it to assume a negative potential. Therefore, the target here is a cathode. The power delivery switch Q7 may also be a MOSFET transistor, and its duty cycle (waveform 1540 in FIG. 15) is controlled so as to provide the proper power from the capacitor to the target (waveform 1550 in FIG. 15). A feedback and control circuitry X1 controls the power delivery to the target by controlling the duty cycle, i.e., pulse width and frequency, of the power delivery switch Q7. The control circuitry X1 may also be used for arc suppression by momentarily turning off power delivery switch Q7 when an arc is detected.

A can be understood, the control circuit coupled to each cathode individually controls the power delivered to that cathode. Consequently, a single power supply may be used to power multiple cathodes with accurate control of the power delivered to each cathode. For example, each power supply may be coupled to 5-10 cathodes, so that a system of 50 sputtering targets may require only 5-10 rather than 50 power supplies.

In the example of FIG. 14A, each sputtering source is also coupled to a positive potential, here 24 volts via a resistor. This positive node provides a path for discharge when the powering switch is turned off, e.g., due to arcing. The discharge path may be coupled to ground potential, however a positive potential provides improved results as it also helps ejecting any positively charged ions that may have been accumulated on the target.

FIG. 14B illustrate another target powering arrangement according to an embodiment of the invention. The embodiment of FIG. 14B is a simplified version of the embodiment of FIG. 14A. Notably, in the embodiment of FIG. 14B the charging switches have been eliminated, so that the power supply is connected directly to the charging capacitors. In this manner, the capacitors are always charged by the power supply and so there is no control over the duty cycle of the charging. Other than that, the embodiment of FIG. 14B is similar to that of FIG. 14A.

As can be understood, in the embodiment of FIG. 14B, the charging capacitors of one bank are connected in parallel, so that their capacitance is summed. The embodiment illustrated in FIG. 14C takes advantage of that fact by simply replacing all of the capacitors of one bank with one large capacitor. In the example of FIG. 14C bank A has one capacitor CA, while bank B has one capacitor CB. Other than that, the embodiment of FIG. 14C is similar to that of FIG. 14B.

Therefore, as can be appreciated, the embodiments of FIGS. 14A-14C may be generalized by reference to a charge accumulator. In FIG. 14A the charge accumulator comprises a plurality of capacitors, each having a switch to control the amount of charge delivered to the capacitor. In FIG. 14B the charge accumulator comprises a plurality of capacitors coupled directly to the power supply. In FIG. 14C the charge accumulator is a single capacitor coupled directly to the power supply. Of course, any other arrangement of charge accumulator may be used.

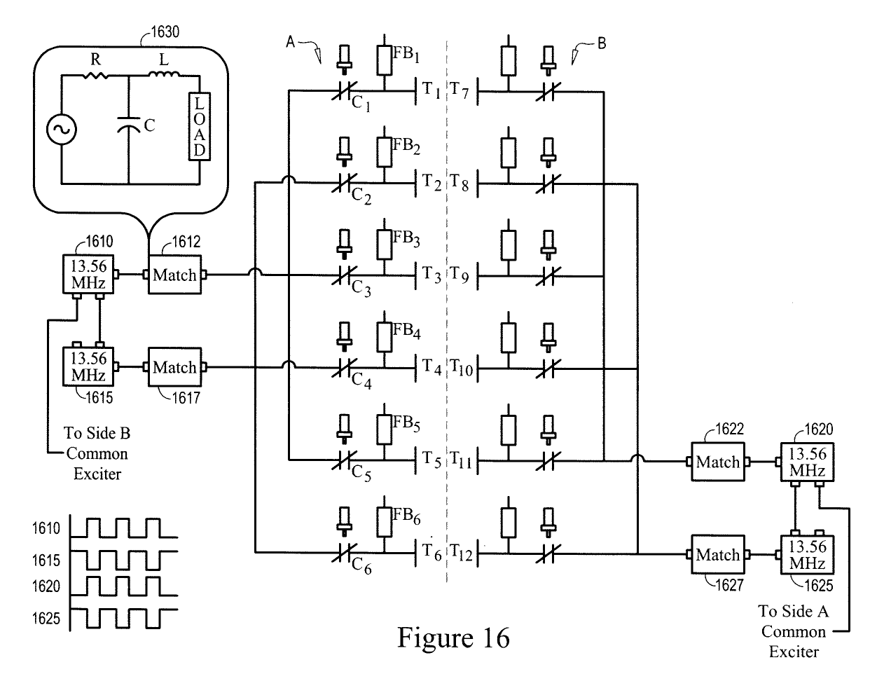

FIG. 16 illustrates an arrangement of power suppliers for a plurality of sputtering targets, according to an embodiment of the invention. This embodiment is optimized for magnetron sputtering, where the magnetron is biased using an RF source. In the example of FIG. 16, bank A is powered by master RF power supply 1610 and slave RF power supply 1615, while bank B is powered by master RF power supply 1620 and slave RF power supply 1625. The master RF power supplies 1610 and 1620 are synchronized to be in phase, while slave RF power supplies 1615 and 1625 are driven at 180 phase shift to the master RF power supplies.

The power supplies 1610, 1615, 1620, 1625 are coupled to impedance match circuits 1612, 1617, 1622, 1627, respectively, in a conventional manner. The impedance match circuits may be implemented using any conventional matching circuits, such as the RLC circuit shown in the callout 1630. The resistance R may simply be the transmission line, which is coupled in series to an inductor L, with shunt capacitor C coupled across the power supply paths. Of course, any other impedance match circuitry may be used.

The impedance match circuits 1612 and 1617 are coupled to sputter sources T1-T6 in an interleaving manner, while impedance match circuits 1622 and 1627 are coupled to sputter sources T7-T12 in an interleaving manner. Consequently, opposing odd numbered sputter sources are driven in phase, e.g., <T1,T7>, <T3,T9>, etc., while neighboring sputtering sources are driven in 180 degree phase in an interleaving manner, e.g., <T1,T2>, <T2,T3>, <T7,T8>, <T8,T9> etc.

As observed by the inventors, although each match circuit would provide the proper matching to provide the power to several sputtering sources, the power would not be delivered equally across the sputtering sources. Therefore, in this example, a further tuning is provided to balance the power across the commonly connected sputtering targets. Load balancing will be explained with respect to bank A.

In this example, bank A comprises six sputtering sources, T1-T6, where T1, T3, and T5 are powered by master RF power supply 1610 and T2, T4 and T6 are powered by slave RF power supply 1615. Each sputtering source is coupled to its respective match circuit via a balancing circuit, here variable capacitors, C1-C6. In this example, a vacuum capacitor is used, which is varied using motor M1-M6. Motorized vacuum capacitors are available off the shelf, and any conventional motorized capacitor having the proper specifications may be used. Feedback circuits FB1-FB6 are used to control the motorized capacitors. In this manner, each match circuitry matches the power delivered by the power supply to its commonly coupled sputtering sources, while the balancing circuits, e.g., the variable capacitors, are used to balance the total power delivered across the commonly coupled sputtering sources.

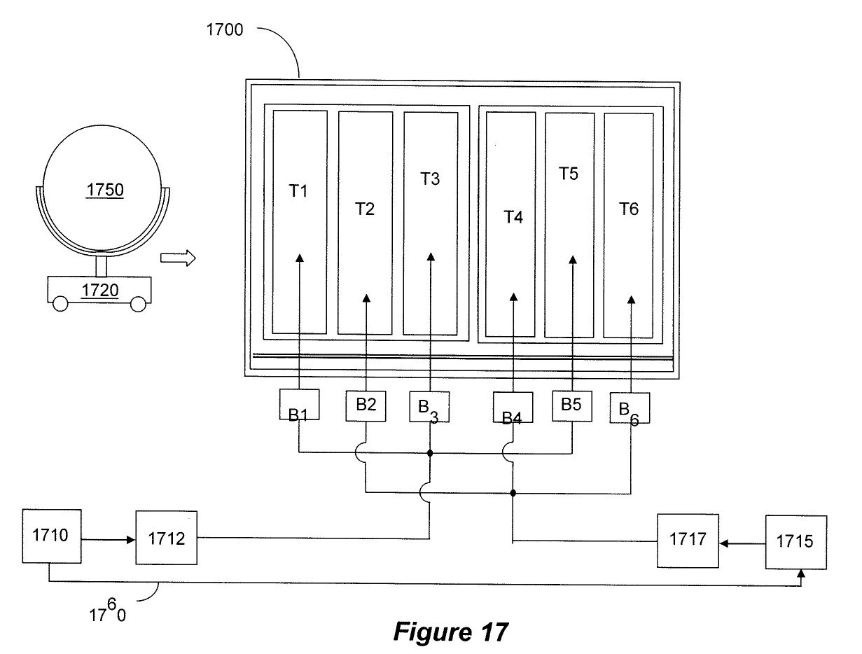

FIG. 17 illustrates an example of a sputtering chamber having multiple sputtering sources energized according to an embodiment of the invention. In FIG. 17, sputtering arrangement 1700 may be a single chamber having multiple sputtering sources, or several chambers abutting each other. Arrangement 1700 would normally form a section of a sputtering system having several arrangements 1700.

The arrangement 1700 has multiple sputtering sources T1-T6 on one side, and corresponding sputtering sources (not shown) on the other side, opposing sources T1-T6. RF power supply 1710 is a master power supply and sends a synch signal 1760 to drive the slave RF power supply 1715 at a 180 degrees phase shift with respect to power supply 1710. Power supply 1710 is coupled to impedance match circuit 1712, while power supply 1715 is coupled to impedance match circuit 1717. Impedance match circuit 1712 is coupled to three sputtering sources, T1, T3 and T5 via three balancing elements B1, B3 and B5, while impedance match circuit 1717 is coupled to three sputtering sources, T2, T4 and T6 via three balancing elements B2, B4 and B6. Consequently, the power delivered to sputtering sources T1, T3 and T5 is at a 180 degrees phase shit to the power delivered to sputtering sources T2, T4 and T6.

As can be understood, as carrier 1720 moves in the direction of the arrow, the substrate 1750 would be exposed serially to sputtering sources T1-T6. In this manner, the substrate 1750 would be coated with material sputtered from sources T1-T6, to form layers of different or same materials thereupon, depending on the materials of the targets of sources T1-T6.

It should be understood that processes and techniques described herein are not inherently related to any particular apparatus and may be implemented by any suitable combination of components. Further, various types of general purpose devices may be used in accordance with the teachings described herein. It may also prove advantageous to construct specialized apparatus to perform the method steps described herein. The present invention has been described in relation to particular examples, which are intended in all respects to be illustrative rather than restrictive. Those skilled in the art will appreciate that many different combinations of hardware, software, and firmware will be suitable for practicing the present invention. For example, the described software may be implemented in a wide variety of programming or scripting languages, such as Assembler, C/C++, perl, shell, PHP, Java, HFSS, CST, EEKO, etc.

The present invention has been described in relation to particular examples, which are intended in all respects to be illustrative rather than restrictive. Those skilled in the art will appreciate that many different combinations of hardware, software, and firmware will be suitable for practicing the present invention. Moreover, other implementations of the invention will be apparent to those skilled in the art from consideration of the specification and practice of the invention disclosed herein. It is intended that the specification and examples be considered as exemplary only, with a true scope and spirit of the invention being indicated by the following claims.

1. A power supply arrangement for concurrently powering multiple sputtering sources, comprising,
a DC power supply;
a charge accumulator coupled to the power supply;
a plurality of power delivery switches, each coupled between the charge accumulator and a respective one of the multiple sputtering sources; and,
a controller activating each of the power delivery switches to individually control the amount of power delivered from the charge accumulator to each of the multiple sputtering sources.

2. The power supply arrangement of claim 1, wherein the charge accumulator comprises a capacitor.

3. The power supply arrangement of claim 1, wherein the charge accumulator comprises a plurality of capacitors, each coupled to one of the power delivery switches.

4. The power supply arrangement of claim 3, further comprising a plurality of charging switches, each coupled between the power supply and one of the plurality of capacitors.

5. The power supply arrangement of claim 1, wherein the controller comprises a plurality of feedback circuits, each coupled to one of the power delivery switches.

6. The power supply arrangement of claim 5, wherein each of the plurality of feedback circuits further comprises arc detection circuit.

7. The power supply arrangement of claim 1, further comprising a plurality of discharge paths, each coupled one of the sputtering sources.

8. The power supply arrangement of claim 7, wherein each of the a plurality of discharge paths comprises a positive potential node.

9. The power supply arrangement of claim 8, wherein the controller comprises a plurality of control circuits, each coupled to one of the power delivery switches.

10. A power supply arrangement for concurrently powering multiple sputtering sources, comprising,
an RF power supply;
an impedance match circuit coupled to the power supply, the impedance match circuit comprising at least one inductor and one capacitor;
a plurality of variable capacitors, each coupled between the impedance match circuit and a respective one of the multiple sputtering sources; and,
a controller activating each of the variable capacitors to individually control the amount of power delivered from the impedance match circuit to each of the multiple sputtering sources.

11. The power supply arrangement of claim 10, wherein each of the variable capacitors comprises a motorized variable vacuum capacitor.

12. The power supply arrangement of claim 11, wherein the controller comprises a plurality of feedback loops, each coupled to a respective motorized variable vacuum capacitor.

13. The power supply arrangement claim 10, further comprising:
a second RF power supply providing an output at 180 degrees phase to the output of the RF power supply;
a second impedance match circuit coupled to the second RF power supply, the second impedance match circuit comprising at least one inductor and one capacitor;
a second set of variable capacitors, each coupled between the second impedance match circuit and a respective one of the multiple sputtering sources that is not coupled to the impedance match circuit; and,
a second controller activating each of the variable capacitors of the second set to individually control the amount of power delivered from the second impedance match circuit.

14. The power supply arrangement of claim 13, wherein the plurality of sputtering sources are arranged in successive order and are coupled to the impedance match circuit and the second impedance match circuit in an interleaving order.

15. The power supply arrangement of claim 14, wherein each of the variable capacitors comprises a motorized variable vacuum capacitor.

16. The power supply arrangement of claim 15, wherein the second controller comprises a second set of feedback loops, each coupled to a respective motorized variable vacuum capacitor.

17. An arrangement for a sputtering system, comprising:
a first set of sputtering sources arranged serially;
a second set of sputtering sources arranged serially and interleaving with the first set;
a third set of sputtering sources arranged in opposing relationship to the first set;
a fourth set of sputtering sources arranged serially and interleaving with the third set and in opposing relationship to the second set;
first, second, third and fourth power sources, the first and third power sources providing in-phase output and the second and fourth power sources providing in-phase output, the second power source providing output in 180 degrees phase shift to the first power source;
first, second, third and fourth match circuits coupled to the first, second, third and fourth power sources, respectively; and,
first, second, third and fourth sets of balancing elements, the first set of balancing elements coupling the first impedance match circuit to the first set of sputtering sources, the second set of balancing elements coupling the second impedance match circuit to the second set of sputtering sources, the third set of balancing elements coupling the third impedance match circuit to the third set of sputtering sources, and the fourth set of balancing elements coupling the fourth impedance match circuit to the fourth set of sputtering sources.

18. The arrangement of claim 17, wherein each of the balancing elements comprises a variable capacitor.

19. The arrangement of claim 18, wherein each variable capacitor comprises a motorized vacuum variable capacitor.

20. The arrangement of claim 19, further comprising a plurality of feedback loops, each coupled to one of the motorized vacuum variable capacitor.
